(19) United States
(12) Patent Application Publication
(10) Pub. No.: US 2025/0141173 A1
(43) Pub. Date: May 1, 2025

(54) MIRROR FOR A LASER, LASER AND LASER COMPONENT

(71) Applicant: ams-OSRAM International GmbH, Regensburg (DE)

(72) Inventors: Peter Fuchs, Regensburg (DE); Christoph Eichler, Donaustauf (DE); Jens Ebbecke, Rohr In Niederbayern (DE)

(73) Assignee: ams-OSRAM International GmbH, Regensburg (DE)

(21) Appl. No.: 18/683,031

(22) PCT Filed: Aug. 8, 2022
(86) PCT No.: PCT/EP2022/072239

§ 371 Date: Feb. 12, 2024

(30) Foreign Application Priority Data
Aug. 13, 2021 (DE) 10 2021 121 115.8

(51) Int. Cl. H01S 3/08

(52) U.S. Cl. CPC H01S 3/08059

(57) ABSTRACT

A mirror for a laser is specified, the mirror including a layer stack having at least a first layer containing a first material and at least a second layer containing a second material, the first material having a first refractive index and the second material having a second refractive index, the first refractive index and the second refractive index differing by at least 0.2, and the reflectivity of the mirror in the event of a first exit medium adjoining the mirror, the first exit medium being translucent at least at points to electromagnetic radiation at a specifiable wavelength, differing by less than 10% from the reflectivity of the mirror in the event of a second exit medium adjoining the mirror. the second exit medium differing from the first exit medium and being translucent at least at points to electromagnetic radiation at the specifiable wavelength, for a wavelength range of at least ±20 nm about the specifiable wavelength. Moreover, a laser and a laser component are specified.

### CROSS-REFERENCE TO RELATED APPLICATIONS

The present application is a national stage entry from International Application No. PCT/EP2022/072239, filed on Aug. 8, 2022, published as International Publication No. WO 2023/016987 Al on Feb. 16, 2023, and claims priority to German Patent Application No. 10 2021 121 115.8, filed Aug. 13, 2021, the disclosures of all of which are hereby incorporated by reference in their entireties.

### FIELD

A mirror for a laser, a laser and a laser component are specified.

### BACKGROUND

In lasers, typically a resonator is formed by arranging an active zone between two mirrors. The power and efficiency of the laser depend, among other things, on the reflectivity of the mirror through which laser radiation is coupled out of the resonator. Mirrors for a resonator can be optimized with regard to various parameters, for example the temperature stability of the laser. This means that the wavelength of the emitted laser radiation changes only slightly with the temperature of the laser. However, the parameters of a mirror, such as its reflectivity, can also depend on an exit medium adjacent to the mirror. This can result in differences in the power and efficiency of the laser depending on the material of the exit medium.

One object to be achieved is to specify a mirror for an efficient laser. Another object to be achieved is to specify an efficient laser. Another object to be achieved is to specify an efficient laser component.

### SUMMARY

According to at least one embodiment of the mirror for a laser, the mirror comprises a layer stack. The layer stack can have several layers. The layers of the layer stack are arranged one above the other in a stacking direction.

The layer stack comprises at least one first layer comprising a first material. The first layer can extend over the entire expansion of the layer stack in a plane that runs perpendicular to the stacking direction. The first layer can exclusively comprise the first material. In other words, the first layer can consist of the first material.

The layer stack further comprises at least one second layer comprising a second material. The second layer can extend over the entire expansion of the layer stack in a plane that runs perpendicular to the stacking direction. The second layer can exclusively comprise the second material. In other words, the second layer can consist of the second material.

According to at least one embodiment of the mirror, the first material has a first refractive index and the second material has a second refractive index. The first refractive index may be different from the second refractive index.

According to at least one embodiment of the mirror, the first refractive index and the second refractive index differ by more than 0.2. This means that the first refractive index is greater than the second refractive index by more than 0.2 or that the second refractive index is greater than the first refractive index by more than 0.2. It is also possible that the first refractive index and the second refractive index differ by more than 0.3, by more than 0.4, by more than 1 or by more than 2.

According to at least one embodiment of the mirror, the reflectivity of the mirror in the case where a first exit medium, which is at least in places translucent for electromagnetic radiation of a predeterminable wavelength, is adjacent to the mirror differs by less than 10% from the reflectivity of the mirror in the case where a second exit medium, which differs from the first exit medium and is at least in places translucent for electromagnetic radiation of the predeterminable wavelength, is adjacent to the mirror, for a wavelength range of at least ±20 nm around the predeterminable wavelength. Wavelengths are specified below as vacuum wavelengths. The reflectivity is the absolute reflectivity in each case. If the mirror is used in a laser, an exit medium is adjacent to the mirror. The properties of this exit medium have an influence on the reflectivity of the mirror. For the mirror specified here, the reflectivity for two different exit media, namely the first exit medium and the second exit medium, differs by less than 10% for a wavelength range of at least ±20 nm around the predeterminable wavelength. This means that the reflectivity of the mirror for the first exit medium has a first reflectivity value. For the second exit medium, the reflectivity of the mirror has a second reflectivity value. The reflectivity is given as a percentage. The first and second reflectivity values differ by less than 10% for a wavelength range of at least ±20 nm around the predeterminable wavelength. This can mean, for example, that the first reflectivity value is 3% and that the second reflectivity value is less than 13% in the range of at least ±20 nm. In the same way, the second reflectivity value can be 3%, for example. The first reflectivity value is then less than 13% in the range of at least ±20 nm.

The exit medium may comprise or consist of air. The other exit medium may comprise or consist of silicone.

The predeterminable wavelength can be an emission wavelength of a laser in which the mirror is arranged.

The predeterminable wavelength can be in a range of wavelengths greater than 800 nm or greater than 900 nm. The wavelength range of at least ±20 nm refers to the wavelengths of the radiation incident on the mirror. The reflectivity of the mirror thus depends on the wavelength of the radiation impinging on the mirror. When the mirror is used in a laser, radiation from the active zone impinges on the mirror.

The fact that the reflectivity of the mirror in the case where the first exit medium is adjacent to the mirror differs by less than 10% from the reflectivity of the mirror in the case where the second exit medium is adjacent to the mirror for a wavelength range of at least ±20 nm around the predeterminable wavelength is achieved by the mirror having the structure described here.

The mirror described here is based, among other things, on the idea that the mirror has very similar reflectivity values for both the first exit medium, which may comprise air, and the second exit medium, which may comprise silicone, at least for a certain wavelength range. This is also possible for other exit media which are translucent at least in places for the predeterminable wavelength. Mirrors for lasers can be optimized with regard to various parameters, such as their temperature stability, which leads to efficient operation of the laser. An optimized mirror can then be used with various exit media adjacent to the mirror. Air and silicone are typical exit media. Typically, however, the mirror has different reflectivity values for the air and silicone exit media or for other possible exit media. As a result, a mirror that has been optimized for the first exit medium can have a significantly different reflectivity when used with the second exit medium, which may be undesirable, for example if reflectivity is increased. In the same way, a mirror that has been optimized for the second exit medium can exhibit a significantly different reflectivity when used with the first exit medium. Under test conditions, it is common to test a laser without encapsulation, for example without silicone as the second exit medium, but only with the first exit medium, for example air. This results in a further disadvantage, namely that the reflectivity of the mirror determined under test conditions is not the reflectivity which it exhibits in later use with an encapsulation comprising silicone, for example.

These disadvantages are avoided with the mirror described here. The mirror has a similar reflectivity for both exit media. This means that the mirror can be optimized for other parameters, such as temperature stability or wavelength stability, and can be used equally advantageously with both exit media. This means that only one setup is required for two different exit media.

In addition, the mirror can be tested and characterized under test conditions with air as the exit medium and also exhibits the optimized properties and a very similar reflectivity as during testing when encapsulated later with, for example, silicone as the second exit medium. This also enables reliable testing of the mirror before further processing such as encapsulation or further assembly of the mirror. During testing, the optical and electronic properties of the laser with the mirror can also be reliably determined for use with the second exit medium. Furthermore, the mirror can be used for different thicknesses of the second exit medium.

The mirror may additionally have the properties of a first or second resonator mirror described in Patent Application DE 10 2020 205 254.9. The content of Patent Application DE 10 2020 205 254.9 is hereby incorporated by reference.

According to at least one embodiment of the mirror, the reflectivity of the mirror in the case where the first exit medium is adjacent to the mirror differs by less than 10% from the reflectivity of the mirror in the case where the second exit medium is adjacent to the mirror, for a wavelength range of at least ±40 nm, preferably ±80 nm, around the predeterminable wavelength.

According to at least one embodiment of the mirror, the reflectivity of the mirror in the case where the first exit medium is adjacent to the mirror differs by less than 10% from the reflectivity of the mirror in the case where the second exit medium is adjacent to the mirror, for a wavelength range from at least 20 nm below the predeterminable wavelength to at least 40 nm above the predeterminable wavelength.

According to at least one embodiment of the mirror, the reflectivity of the mirror in the case where the first exit medium is adjacent to the mirror differs by less than 5% from the reflectivity of the mirror in the case where the second exit medium is adjacent to the mirror, for a wavelength range of at least ±20 nm, preferably ±40 nm, particularly preferably ±80 nm, around the predeterminable wavelength.

According to at least one embodiment of the mirror for a laser, the mirror comprises a layer stack having at least one first layer comprising a first material and at least one second layer comprising a second material, wherein the first material has a first refractive index and the second material has a second refractive index, and the first refractive index and the second refractive index differ by at least 0.2. With this structure of the mirror, it is achieved that the reflectivity of the mirror in the case where the first exit medium is adjacent to the mirror differs by less than 10% from the reflectivity of the mirror in the case where the second exit medium is adjacent to the mirror, for a wavelength range of at least ±20 nm around the predeterminable wavelength. This makes it possible to optimize the reflectivity of the mirror for both exit media. The laser can therefore be operated efficiently in both cases.

According to at least one embodiment of the mirror, the reflectivity of the mirror in the case where the first exit medium is adjacent to the mirror differs by less than 1% from the reflectivity of the mirror in the case where the second exit medium is adjacent to the mirror, for a wavelength range of at least ±20 nm around the predeterminable wavelength. This small difference in reflectivity when using the two exit media prevents significant differences in the reflectivity of the mirror compared to the mirror tested with the first exit medium when using the other exit medium. This means that if the mirror has been tested with the first exit medium, it will also have very similar properties when used later with the second exit medium. This makes it possible to optimize the reflectivity of the mirror for both exit media. The laser can therefore be operated efficiently in both cases.

According to at least one embodiment of the mirror, the reflectivity of the mirror in the case where the first exit medium is adjacent to the mirror differs by less than 1% from the reflectivity of the mirror in the case where the second exit medium is adjacent to the mirror, for a wavelength range of at least ±40 nm, preferably ±80 nm, around the predeterminable wavelength.

According to at least one embodiment of the mirror, the reflectivity of the mirror in the case where the first exit medium is adjacent to the mirror differs by less than 0.5% from the reflectivity of the mirror in the case where the second exit medium is adjacent to the mirror, for a wavelength range of at least ±20 nm, preferably ±40 nm, particularly preferably ±80 nm, around the predeterminable wavelength.

According to at least one embodiment of the mirror, the reflectivity of the mirror in the case where the first exit medium is adjacent to the mirror and in the case where the second exit medium is adjacent to the mirror is less than 3% for a wavelength range of at least 40 nm. This means that the reflectivity of the mirror is less than 3% for a wavelength range of at least 40 nm when the mirror is used in a laser and the mirror is adjacent to the first exit medium. Furthermore, the reflectivity of the mirror is less than 3% for a wavelength range of at least 40 nm when the mirror is used in a laser and the mirror is adjacent to the second exit medium.

The mirror can thus advantageously be used in a laser to influence the wavelength range in which the emitted laser radiation lies. For example, the mirror has a reflectivity of less than 3% in the wavelength range of at least 40 nm, which means that electromagnetic radiation in this wavelength range is largely not reflected by the mirror and exits the laser. Electromagnetic radiation in this wavelength range therefore does not exceed the laser threshold when the laser is in operation. This means that the laser radiation emitted by the laser during operation is in a wavelength range other than the wavelength range of at least 40 nm. The mirror can have a significantly higher reflectivity than 3% in the other wavelength range. Thus, the use of the mirror can advantageously influence the wavelength range of the laser radiation emitted by the laser during operation. This is advantageously possible for both the first exit medium and the second exit medium. The mirror thus has the effect of an edge filter. The reflectivity of less than 3% is a residual reflectivity.

A particularly low reflectivity of the mirror, such as less than 3%, contributes to a stabilization of the wavelength of the laser radiation emitted by the laser during operation in a wavelength range which is different from the wavelength range in which the reflectivity of the mirror is less than 3%. The low reflectivity of the mirror of less than 3% is achieved by the structure of the mirror described here. The stabilization of the wavelength of the laser radiation emitted by the laser during operation enables efficient operation of the laser. For example, no external components are required for wavelength stabilization.

According to at least one embodiment of the mirror, the reflectivity of the mirror in the case where the first exit medium is adjacent to the mirror and in the case where the second exit medium is adjacent to the mirror is less than 3% for a wavelength range of at least 80 nm, preferably at least 160 nm.

According to at least one embodiment of the mirror, the reflectivity of the mirror in the case where the first exit medium is adjacent to the mirror and in the case where the second exit medium is adjacent to the mirror is less than 2% for a wavelength range of at least 40 nm, preferably at least 80 nm and particularly preferably at least 160 nm.

According to at least one embodiment of the mirror, the reflectivity of the mirror in the case where the first exit medium is adjacent to the mirror and in the case where the second exit medium is adjacent to the mirror is less than 5% for a wavelength range of at least 40 nm, preferably at least 80 nm and particularly preferably at least 160 nm.

According to at least one embodiment of the mirror, the wavelength range of at least 40 nm extends over wavelengths which are greater than a target wavelength of the laser. The target wavelength of the laser is the wavelength of the laser radiation that the laser emits during operation. This means that the wavelength range of at least 40 nm extends over a range in which emission of laser radiation by the laser is not desired. The emission of laser radiation in the wavelength range of at least 40 nm is prevented by the low reflectivity of the mirror in this wavelength range. For example, the target wavelength of the laser is 900 nm and the wavelength range of at least 40 nm extends over the wavelengths from 910 to 950 nm. The mirror therefore has the effect of an edge filter.

According to at least one embodiment of the mirror, the wavelength range of at least 80 nm extends over wavelengths which are greater than the target wavelength of the laser.

According to at least one embodiment of the mirror, the wavelength range of at least 160 nm extends over wavelengths which are greater than the target wavelength of the laser.

According to at least one embodiment of the mirror, the first material and the second material each comprise at least one of an oxide, a nitride and an oxynitride. The first material and the second material may be different from each other. The first material and the second material may each consist of at least one of an oxide, a nitride and an oxynitride. These material combinations in the layer stack of the mirror advantageously allow the reflectivity of the mirror in the case where the first exit medium is adjacent to the mirror to differ by less than 10% from the reflectivity of the mirror in the case where the second exit medium is adjacent to the mirror, for a wavelength range of at least ±20 nm around the predeterminable wavelength. In particular, these material combinations in the layer stack advantageously allow the reflectivity of the mirror in the case where the first exit medium is adjacent to the mirror and in the case where the second exit medium is adjacent to the mirror to be less than 3% for a wavelength range of at least 40 nm. This means that the properties of the mirror are obtained by its structure. Due to the low reflectivity of the mirror of less than 3% for the wavelength range of at least 40 nm, the wavelength of the laser radiation emitted by the laser during operation can be stabilized, which enables efficient operation of the laser.

According to at least one embodiment of the mirror, the layer stack comprises a further first layer comprising the first material and a further second layer comprising the second material, wherein the further first layer is arranged between the second layer and the further second layer. This means that the further first layer is arranged between the second layer and the further second layer in the stacking direction. The second layer may be arranged between the first layer and the further first layer. The further first layer can consist of the first material. The further second layer can consist of the second material.

The further first layer may have a layer thickness along the stacking direction which is different from the layer thickness of the first layer along the stacking direction. The further second layer can have a layer thickness along the stacking direction that is different from the layer thickness of the second layer along the stacking direction. Overall, all layers of the layer stack can have different layer thicknesses along the stacking direction. The first layer and the further first layer can each have a layer thickness along the stacking direction that is less than 100 nm. The second layer and the further second layer can each have a layer thickness along the stacking direction that is less than 160 nm.

This structure of the layer stack with the further first layer and the further second layer advantageously allows the reflectivity of the mirror in the case where the first exit medium is adjacent to the mirror to differ by less than 10% from the reflectivity of the mirror in the case where the second exit medium is adjacent to the mirror, for a wavelength range of at least ±20 nm around the predeterminable wavelength. In particular, this structure of the layer stack advantageously allows the reflectivity of the mirror in the case where the first exit medium is adjacent to the mirror and in the case where the second exit medium is adjacent to the mirror to be less than 3% for a wavelength range of at least 40 nm.

According to at least one embodiment of the mirror, the layer thickness of each layer of the layer stack is at most 500 nm. This means that the layer thickness of each layer of the layer stack is at most 500 nm along the stacking direction. Preferably, the layer thickness of each layer of the layer stack is at most 300 nm or 200 nm. It is further possible that the layer thickness of each layer of the layer stack is at most 1000 nm. This structure of the layer stack advantageously allows the reflectivity of the mirror in the case where the first exit medium is adjacent to the mirror to differ by less than 10% from the reflectivity of the mirror in the case where the second exit medium is adjacent to the mirror, for a wavelength range of at least ±20 nm around the predeterminable wavelength. In particular, this structure of the layer stack advantageously allows the reflectivity of the mirror in the case where the first exit medium is adjacent to the mirror and in the case where the second exit medium is adjacent to the mirror to be less than 3% for a wavelength range of at least 40 nm.

According to at least one embodiment of the mirror, the first material and the second material each comprise at least one of the following substances: Al, Ce, Ga, Hf, In, Mg, Nb, Rh, Sb, Si, Sn, Ta, Ti, Zn, Zr. It is also possible that the first material and the second material each comprise exactly one of these substances. It is also possible that the first material and the second material each comprise at least one of an oxide, a nitride and an oxynitride with at least one of these substances. Advantageously, these compositions of the first layer and the second layer allow the reflectivity of the mirror in the case where the first exit medium is adjacent to the mirror to differ by less than 10% from the reflectivity of the mirror in the case where the second exit medium is adjacent to the mirror, for a wavelength range of at least ±20 nm around the predeterminable wavelength. In particular, these compositions of the first layer and the second layer advantageously allow the reflectivity of the mirror in the case where the first exit medium is adjacent to the mirror and in the case where the second exit medium is adjacent to the mirror to be less than 3% for a wavelength range of at least 40 nm.

According to at least one embodiment of the mirror, the first material comprises aluminum oxide. It is also possible that the first material consists of aluminum oxide.

According to at least one embodiment of the mirror, the second material comprises tantalum oxide. It is also possible that the second material consists of tantalum oxide.

These compositions of the first layer and the second layer advantageously allow the reflectivity of the mirror in the case where the first exit medium is adjacent to the mirror to differ by less than 10% from the reflectivity of the mirror in the case where the second exit medium is adjacent to the mirror, for a wavelength range of at least ±20 nm around the predeterminable wavelength. In particular, these compositions of the first layer and the second layer advantageously allow the reflectivity of the mirror in the case where the first exit medium is adjacent to the mirror and in the case where the second exit medium is adjacent to the mirror to be less than 3% for a wavelength range of at least 40 nm.

According to at least one embodiment of the mirror, the layer stack has a total of three first layers, three second layers and three third layers, wherein the third layers each comprise a third material. The three first layers each comprise the first material and have different layer thicknesses along the stacking direction. The three second layers each comprise the second material and have different layer thicknesses along the stacking direction. The three third layers each have different layer thicknesses along the stacking direction. The three third layers can each consist of the third material. The third material can be different from the first material and the second material. This structure of the layer stack advantageously allows the reflectivity of the mirror in the case where the first exit medium is adjacent to the mirror to differ by less than 10% from the reflectivity of the mirror in the case where the second exit medium is adjacent to the mirror, for a wavelength range of at least ±20 nm around the predeterminable wavelength. In particular, this structure of the layer stack advantageously allows the reflectivity of the mirror in the case where the first exit medium is adjacent to the mirror and in the case where the second exit medium is adjacent to the mirror to be less than 3% for a wavelength range of at least 40 nm.

According to at least one embodiment of the mirror, the third material comprises silicon. The third material may consist of silicon. This structure of the layer stack with a third material comprising silicon advantageously allows the reflectivity of the mirror in the case where the first exit medium is adjacent to the mirror to differ by less than 10% from the reflectivity of the mirror in the case where the second exit medium is adjacent to the mirror, for a wavelength range of at least ±20 nm around the predeterminable wavelength. In particular, this structure of the layer stack advantageously allows the reflectivity of the mirror in the case where the first exit medium is adjacent to the mirror and in the case where the second exit medium is adjacent to the mirror to be less than 3% for a wavelength range of at least 40 nm.

According to at least one embodiment of the mirror, the layer stack has a total of five first layers and five second layers. The five first layers each comprise the first material and have different layer thicknesses along the stacking direction. The five second layers each comprise the second material and have different layer thicknesses along the stacking direction. The first and second layers are arranged alternately. The first layers each have a layer thickness of at most 270 nm along the stacking direction. The second layers each have a layer thickness of at most 170 nm along the stacking direction. This structure of the layer stack advantageously allows the reflectivity of the mirror in the case where the first exit medium is adjacent to the mirror to differ by less than 10% from the reflectivity of the mirror in the case where the second exit medium is adjacent to the mirror, for a wavelength range of at least ±20 nm around the predeterminable wavelength. In particular, this structure of the layer stack advantageously allows the reflectivity of the mirror in the case where the first exit medium is adjacent to the mirror and in the case where the second exit medium is adjacent to the mirror to be less than 3% for a wavelength range of at least 40 nm.

Furthermore, a laser is specified. According to at least one embodiment of the laser, the laser comprises the mirror. In other words, all features disclosed for the mirror are also disclosed for the laser. The laser has an active zone and a further mirror, and the active zone is arranged between the mirror and the further mirror. The further mirror may have a structure which is different from the structure of the mirror. It is also possible for the further mirror to have the same properties as a mirror described here. The laser also has the advantages mentioned for the mirror. The laser can be an edge-emitting laser. It is also possible for the laser to be vertical-emitting or surface-emitting. The laser can be a pulse laser. The laser can be used in the field of distance measurements, for example.

According to at least one embodiment of the laser, the first exit medium or the second exit medium, which has an extension along a main extension direction of the active zone of at least 1 μm, is arranged on the side of the mirror facing away from the active zone. This means that either the first exit medium or the second exit medium is arranged on the side of the mirror facing away from the active zone. The first exit medium or the second exit medium extends along the main extension direction of the active zone over a distance of at least 1 μm. Preferably, the first exit medium or the second exit medium has an extension along the main extension direction of the active zone of at least 10 μm. Particularly preferably, the first exit medium or the second exit medium has an extension along the main extension direction of the active zone of at least 100 μm.

The first exit medium or the second exit medium can be adjacent to the entire side of the mirror facing away from the active zone. The first exit medium or the second exit medium can be exclusively adjacent to the mirror. In this case, the first exit medium or the second exit medium are not adjacent to any other area of the laser. A deflecting mirror can be arranged in the first exit medium or in the second exit medium. The deflecting mirror is configured to deflect laser radiation emitted through the mirror. It is also possible for the laser to be completely surrounded by the first exit medium or the second exit medium. It is also possible that an optical element, for example a lens, is arranged on the side of the first exit medium or the second exit medium facing away from the mirror.

The extension of the first exit medium or the second exit medium of at least 1 μm prevents further reflections at the interface of the first exit medium or the second exit medium on the side opposite the mirror. The interface is the surface of the first exit medium or the second exit medium which is adjacent to the medium surrounding the first exit medium or the second exit medium. By avoiding further reflections that could re-enter the active zone, destabilization of the wavelength of the laser radiation emitted by the laser is prevented. The laser can therefore be operated efficiently.

Furthermore, a laser component is specified. According to at least one embodiment of the laser component, the laser component comprises the laser. In other words, all features disclosed for the laser are also disclosed for the laser component. The laser component further comprises the first exit medium or the second exit medium.

According to at least one embodiment of the laser component, the laser component has an optical element adjacent to the first exit medium or the second exit medium. The optical element may be a lens.

According to at least one embodiment of the laser component, a coating is arranged between the optical element and the first exit medium or the second exit medium, which coating has a reflectivity of less than 2% for the predeterminable wavelength. Preferably, the coating has a reflectivity of less than 1% or less than 0.5% for the predeterminable wavelength.

According to at least one embodiment of the laser component, the mirror has a main extension plane which is parallel to the main extension plane of the active zone. The further mirror can also have a main extension plane that is parallel to the main extension plane of the active zone. The laser component can have two deflection mirrors so that laser radiation generated during operation can be reflected to the mirror and to the further mirror via the deflection mirrors. The first exit medium or the second exit medium is adjacent to the mirror on an upper side of the laser component, so that the laser radiation emitted during operation exits the laser component on the upper side. Thus, the laser component is advantageously designed to emit laser radiation in a direction perpendicular to the main extension plane of the active zone.

In the following, the mirror described here and the laser described here are explained in more detail in conjunction with exemplary embodiments and the associated figures.

### BRIEF DESCRIPTION OF THE DRAWINGS

FIG. 1 shows a schematic cross-section of a mirror according to an exemplary embodiment.

FIGS. 2A, 2B, 3 and 4 show schematic cross-sections of mirrors according to further exemplary embodiments.

FIG. 5 shows the reflectivity of a mirror according to an exemplary embodiment plotted against the wavelength.

FIG. 6 shows a schematic cross-section of a laser according to an exemplary embodiment.

FIGS. 7, 8 and 9 show schematic cross-sections of lasers according to further exemplary embodiments.

FIGS. 10, 11, 12, 13 and 14 show the reflectivity of a mirror according to various exemplary embodiments plotted against the wavelength.

### DETAILED DESCRIPTION

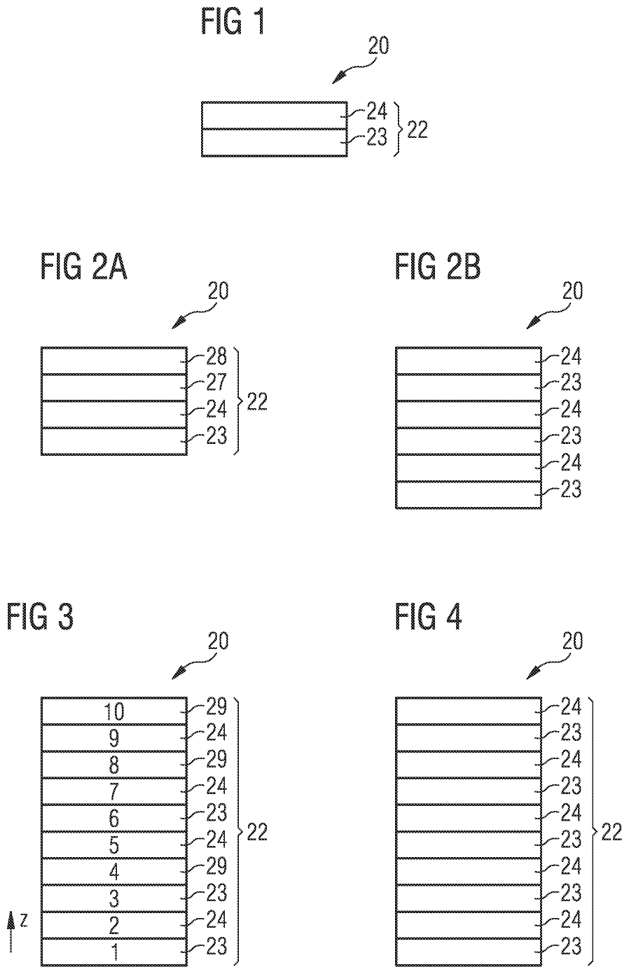

FIG. 1 shows a schematic cross-section of a mirror 20 for a laser 21 according to an exemplary embodiment. The mirror 20 comprises a layer stack 22 having a first layer 23 comprising a first material and a second layer 24 comprising a second material. The first material has a first refractive index and the second material has a second refractive index, wherein the first refractive index and the second refractive index differ by at least 0.2.

The mirror 20 can be used in a laser 21. In this case, either a first exit medium 25 or a second exit medium 26 is adjacent to the mirror 20. The first exit medium 25 and the second exit medium 26 are at least in places translucent for electromagnetic radiation of a predeterminable wavelength. The first exit medium 25 may comprise air. The second exit medium 26 may comprise silicone. The reflectivity R of the mirror 20 in the case where the first exit medium 25 is adjacent to the mirror 20 differs by less than 10% from the reflectivity R of the mirror 20 in the case where the second exit medium 26 is adjacent to the mirror 20, for a wavelength range of at least ±20 nm around the predeterminable wavelength. Furthermore, the reflectivity R of the mirror 20 in the case where the first exit medium 25 is adjacent to the mirror 20 and in the case where the second exit medium 26 is adjacent to the mirror 20 is less than 3% for a wavelength range of at least 40 nm. In this case, the wavelength range of at least 40 nm extends over wavelengths which are greater than a target wavelength of the laser 21.

The first material and the second material each comprise at least one of an oxide, a nitride and an oxynitride. In addition, the first material and the second material may each comprise at least one of the following substances: Al, Ce, Ga, Hf, In, Mg, Nb, Rh, Sb, Si, Sn, Ta, Ti, Zn, Zr. The layer thickness of each layer of the layer stack 22 is at most 500 nm.

FIG. 2A shows a schematic cross-section of the mirror 20 for a laser 21 according to a further exemplary embodiment. In comparison to the exemplary embodiment shown in FIG. 1, the layer stack 22 of the mirror 20 additionally has a further first layer 27, which comprises the first material, and a further second layer 28, which comprises the second material. Here, the further first layer 27 is arranged between the second layer 24 and the further second layer 28. Furthermore, the second layer 24 is arranged between the first layer 23 and the further first layer 27. The mirror 20 can also have the characteristics described in FIG. 1.

FIG. 2B shows a schematic cross-section of the mirror 20 for a laser 21 according to a further exemplary embodiment. The layer stack has three first layers 23 and three second layers 24. The first layers 23 and the second layers 24 are arranged alternately. The first layers 23 each comprise aluminum oxide. The second layers 24 each comprise tantalum oxide. The layer thickness of each layer of the layer stack 22 is at most 100 nm.

FIG. 3 shows a schematic cross-section of the mirror 20 for a laser 21 according to a further exemplary embodiment. The layer stack 22 has a total of three first layers 23, four second layers 24 and three third layers 29. The third layers 29 each comprise a third material. The first material comprises aluminum oxide. The second material comprises tantalum oxide, and the third material comprises silicon. It is possible that the first layers 23 each consist of aluminum oxide, that the second layers 24 each consist of tantalum oxide, and that the third layers 29 each consist of silicon. The layers of the layer stack 22 have different layer thicknesses from one another.

The layers of the layer stack 22 are numbered from bottom to top in the stacking direction z with the numbers 1 to 10. The described advantages of the mirror 20 are obtained for the following structure of the layer stack 22. Layer number 1 is a first layer 23. Layer number 2 is a second layer 24. Layer number 3 is a first layer 23. Layer number 4 is a third layer 29. Layer number 5 is a second layer 24. Layer number 6 is a first layer 23. Layer number 7 is a second layer 24. Layer number 8 is a third layer 29. Layer number 9 is a second layer 24. Layer number 10 is a third layer 29.

The layers of the layer stack 22 can have the following extensions along the stacking direction z:
Layer no. 1: 34 nm
Layer no. 2: 157 nm
Layer no. 3: 37 nm
Layer no. 4: 139 nm
Layer no. 5: 50 nm
Layer no. 6: 92 nm
Layer no. 7: 1 nm
Layer no. 8: 3 nm
Layer no. 9: 42 nm
Layer no. 10: 104 nm

For this structure of the layer stack 22 of the mirror 20, the reflectivity R of the mirror 20 in the case where the first exit medium 25 is adjacent to the mirror 20 differs by less than 1% from the reflectivity R of the mirror 20 in the case where the second exit medium 26 is adjacent to the mirror 20, for a wavelength range of at least ±20 nm around the predeterminable wavelength.

FIG. 4 shows a schematic cross-section of the mirror 20 for a laser 21 according to a further exemplary embodiment. The layer stack 22 of the mirror 20 has a total of five first layers 23 and five second layers 24. The first layers 23 and the second layers 24 are arranged alternately.

FIG. 5 shows the reflectivity R of the mirror 20 according to an exemplary embodiment for a certain wavelength range. The wavelength of the radiation incident on the mirror 20 is plotted in nanometers on the x-axis and the reflectivity R of the mirror 20 shown in FIG. 3 is plotted as a percentage on the y-axis. The reflectivity R is plotted firstly for the case where the first exit medium 25, which comprises air, is adjacent to the mirror 20. In addition, the reflectivity R is plotted for the case where the second exit medium 26, which comprises silicone, is adjacent to the mirror 20. The reflectivity R has very similar values in both cases. For example, the reflectivity R in both cases differs by less than 1% for a wavelength range from 880 nm to 950 nm. In addition, the reflectivity R in both cases is less than 3% for a wavelength range from 910 nm to 950 nm. Thus, the mirror 20 shown in FIG. 3 achieves the described advantages. For example, a stabilization of the wavelength of the laser radiation emitted by the laser 21 during operation can be achieved, since the laser 21 has a low residual reflectivity in the wavelength range from 910 nm to 950 nm. With the structure of the mirror 20 shown in FIG. 4, similar values of reflectivity R as shown in FIG. 5 can be achieved.

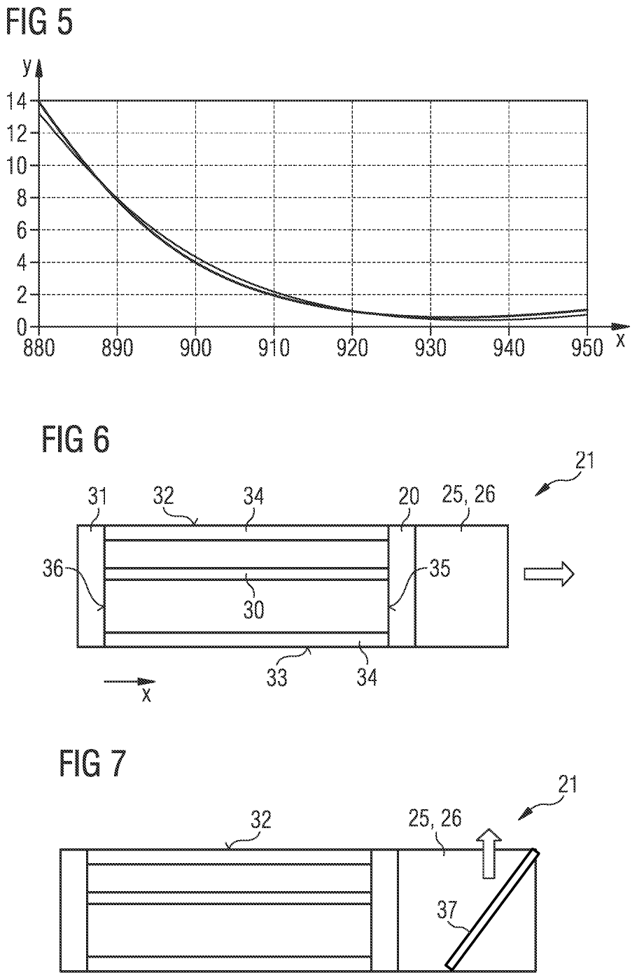

FIG. 6 shows a schematic cross-section of a laser 21 according to an exemplary embodiment. The laser 21 is an edge-emitting laser. The laser 21 comprises the mirror 20, an active zone 30 and a further mirror 31. The active zone 30 is arranged between the mirror 20 and the further mirror 31. The active zone 30 is arranged between the mirror 20 and the further mirror 31 along its main extension direction x. The laser 21 has an upper side 32 and a lower side 33 facing away from the upper side 32. An electrical contact 34 is arranged on the upper side 32 and on the lower side 33. The laser 21 further has a first side 35 and a second side 36, the second side 36 being arranged on the side of the laser 21 facing away from the first side 35. The mirror 20 is arranged on the first side 35 of the laser 21. The further mirror 31 is arranged on the second side 36 of the laser 21. The first exit medium 25 or the second exit medium 26 is arranged adjacent to the mirror 20. The first exit medium 25 or the second exit medium 26 is arranged at least on the side of the mirror 20 facing away from the active zone 30. Laser radiation emitted by the laser 21 during operation can exit the laser 21 through the mirror 20 and the first exit medium 25 or the second exit medium 26, which is shown with an arrow.

The first exit medium 25 or the second exit medium 26 has an extension along the main extension direction x of the active zone 30 of at least 1 μm. Thus, further reflections at the interface of the first exit medium 25 or the second exit medium 26 with the medium surrounding the first exit medium 25 or the second exit medium 26 are avoided. This extension of at least 1 μm is particularly important for the second exit medium 26, which comprises silicone, as lasers are usually used in air, resulting in an interface with air for the second exit medium 26 on the side facing away from the mirror 20. This interface does not occur for the first exit medium 25, which comprises air, when the laser 21 is used in air.

FIG. 7 shows a schematic cross-section of the laser 21 according to a further exemplary embodiment. Here, the laser 21 has the structure shown in FIG. 6 with the difference that a deflecting mirror 37 is arranged in the first exit medium 25 or in the second exit medium 26. Laser radiation emitted by the laser 21 is deflected via the deflecting mirror 37 so that it is emitted on the upper side 32.

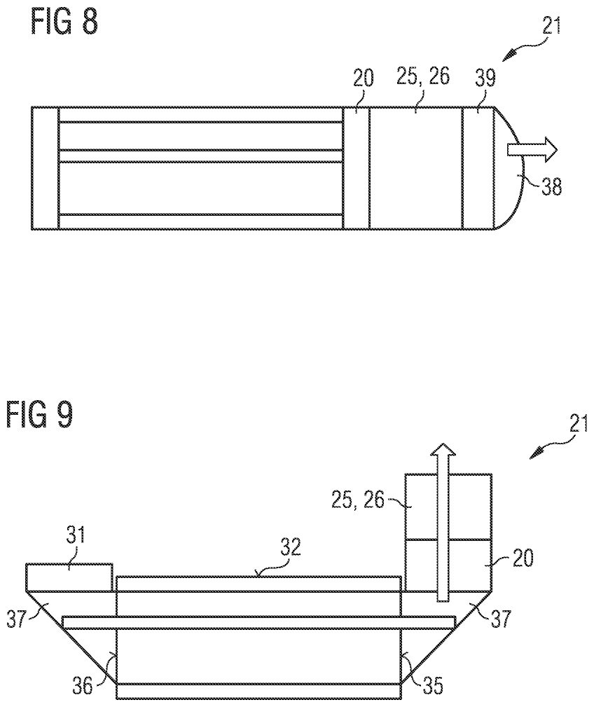

FIG. 8 shows a schematic cross-section of the laser 21 according to a further exemplary embodiment. Here, the laser 21 has the structure shown in FIG. 6 with the difference that a lens 38 is arranged on the side of the first exit medium 25 or the second exit medium 26 facing away from the mirror 20. The lens 38 has a coating 39 on the side facing the mirror 20. The coating 39 is an anti-reflective coating. This prevents further reflections at the interface between the first exit medium 25 or the second exit medium 26 and the lens 38.

FIG. 9 shows a schematic cross-section of the laser 21 according to a further exemplary embodiment. The laser 21 has the structure shown in FIG. 6, with the difference that the laser 21 is a vertical-emitting laser. The mirror 20 and the further mirror 31 are arranged on the upper side 32 of the laser 21. On the first side 35 and on the second side 36, the laser 21 has integrated deflecting mirrors 37, so that laser radiation generated during operation is reflected via the deflecting mirrors 37 to the mirror 20 and to the further mirror 31 by means of total internal reflection. The first exit medium 25 or the second exit medium 26 is adjacent to the mirror 20 on the upper side 32, so that the laser radiation emitted during operation exits the laser 21 on the upper side 32.

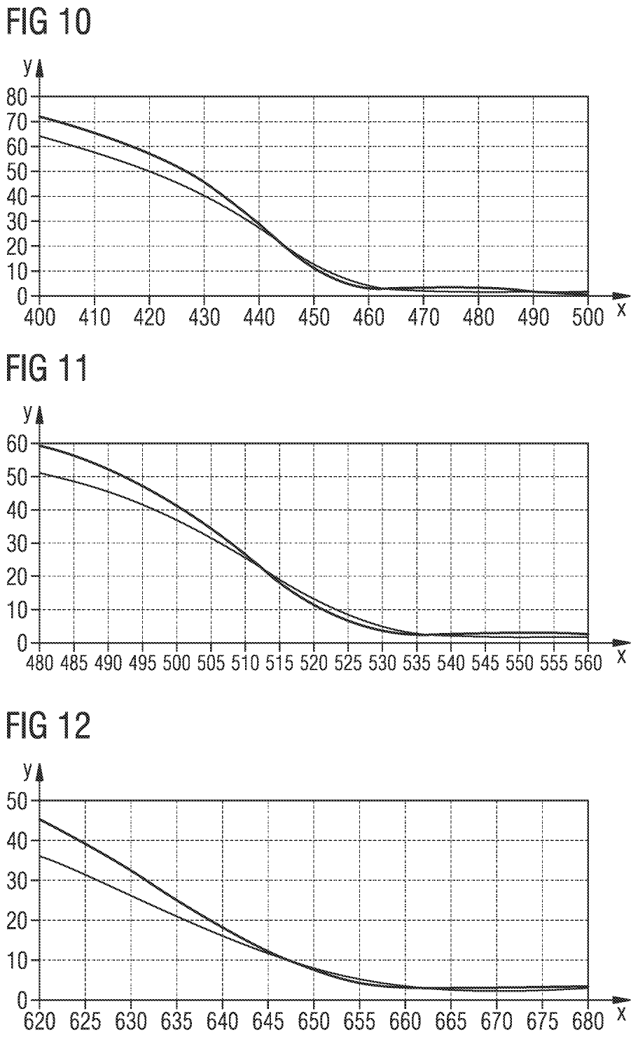

FIG. 10 shows the reflectivity R of the mirror 20 according to a further exemplary embodiment for a certain wavelength range. The wavelength of the radiation incident on the mirror 20 is plotted in nanometers on the x-axis and the reflectivity R of the mirror 20 is plotted as a percentage on the y-axis. The reflectivity R is plotted firstly for the case where the first exit medium 25, which comprises air, is adjacent to the mirror 20. In addition, the reflectivity R is plotted for the case where the second exit medium 26, which comprises silicone, is adjacent to the mirror 20. The reflectivity R has very similar values in both cases. For example, the reflectivity R differs in both cases by less than 5% for a wavelength range from 440 nm to 500 nm. The emission wavelength of a laser 21 in which the mirror 20 is used can be in the blue spectral range. The first refractive index and the second refractive index differ by more than 0.5. The first material comprises SiO₂ and the second material comprises tantalum oxide. The layer stack 22 has six first layers 23 and six second layers 24. The first layers 23 and the second layers 24 are arranged alternately on top of each other. The layer thickness of each layer of the layer stack 22 is at least 5 nm and at most 160 nm.

FIG. 11 shows the reflectivity R of the mirror 20 according to a further exemplary embodiment for a certain wavelength range. The reflectivity R is shown as described in FIG. 10. In both cases, the reflectivity R differs by less than 5% for a wavelength range from 505 nm to 560 nm. The emission wavelength of a laser 21 in which the mirror 20 is used can be in the green spectral range. The first refractive index and the second refractive index differ by more than 0.5. The first material comprises SiO₂ and the second material comprises tantalum oxide. The layer stack 22 has six first layers 23 and six second layers 24. The first layers 23 and the second layers 24 are arranged alternately on top of each other. The layer thickness of each layer of the layer stack 22 is at least 8 nm and at most 190 nm.

FIG. 12 shows the reflectivity R of the mirror 20 according to a further exemplary embodiment for a certain wavelength range. The reflectivity R is shown as described in FIG. 10. In both cases, the reflectivity R differs by less than 5% for a wavelength range from 640 nm to 680 nm. The emission wavelength of a laser 21 in which the mirror 20 is used can be in the red spectral range. The first refractive index and the second refractive index differ by more than 0.5. The first material comprises SiO₂ and the second material comprises tantalum oxide. The layer stack 22 has six first layers 23 and six second layers 24. The first layers 23 and the second layers 24 are arranged alternately on top of each other. The layer thickness of each layer of the layer stack 22 is at least 8 nm and at most 160 nm.

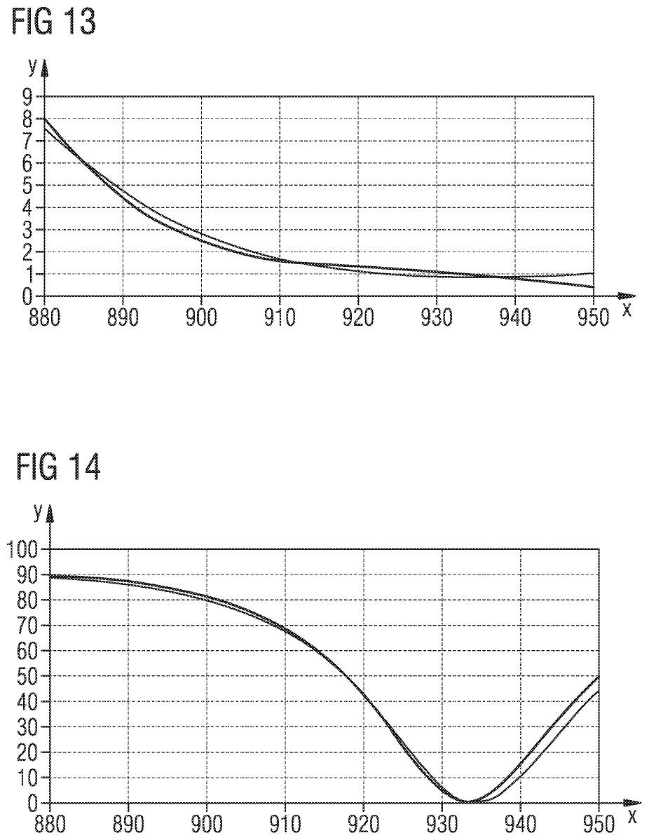

FIG. 13 shows the reflectivity R of the mirror 20 according to a further exemplary embodiment for a certain wavelength range. The reflectivity R is shown as described in FIG. 10. In both cases, the reflectivity R differs by less than 1% for a wavelength range from 880 nm to 950 nm. The emission wavelength of a laser 21 in which the mirror 20 is used can be in the infrared spectral range. The layer stack 22 has a total of three first layers 23, three second layers 24 and three third layers 29. The third layers 29 each have a third material. The first material comprises aluminum oxide. The second material comprises tantalum oxide, and the third material comprises SiO₂. It is possible that the first layers 23 each consist of aluminum oxide, that the second layers 24 each consist of tantalum oxide, and that the third layers 29 each consist of SiO₂. The layers of the layer stack 22 have different layer thicknesses from one another.

The described advantages of the mirror 20 are achieved for the following structure of the layer stack 22. The first layer of the layer stack is a first layer 23. A third layer 29 is arranged on the first layer 23. A second layer 24 is arranged on the third layer 29. A first layer 23 is arranged on the second layer 24. A third layer 29 is arranged on the first layer 23. A second layer 24 is arranged on the third layer 29. A first layer 23 is arranged on the second layer 24. A third layer 29 is arranged on the first layer 23. A second layer 24 is arranged on the third layer 29.

The layers of the layer stack 22 can have the following extensions along the stacking direction z:
First layer: 99 nm
Third layer: 217 nm
Second layer: 95 nm
First layer: 38 nm
Third layer: 153 nm
Second layer: 224 nm
First layer: 179 nm
Third layer: 85 nm
Second layer: 236 nm

For this structure of the layer stack 22 of the mirror 20, the reflectivity R of the mirror 20 in the case where the first exit medium 25 is adjacent to the mirror 20 differs by less than 1% from the reflectivity R of the mirror 20 in the case where the second exit medium 26 is adjacent to the mirror 20, for a wavelength range of at least ±20 nm around the predeterminable wavelength.

FIG. 14 shows the reflectivity R of the mirror 20 according to a further exemplary embodiment for a certain wavelength range. The reflectivity R is shown as described in FIG. 10. In both cases, the reflectivity R differs by less than 5% for a wavelength range from 880 nm to 940 nm. The emission wavelength of a laser 21 in which the mirror 20 is used can be in the infrared spectral range. This mirror 20 has a higher reflectivity R than the other mirrors 20 described.

The mirror 20 whose reflectivity R is shown in FIG. 14 can be used in a laser 21 on the side opposite an exit side. Thus, this mirror 20 is not the exit mirror of the laser 21. The mirror 20 has a higher reflectivity R than an exit mirror, at least for some wavelengths. For example, a laser 21 can have a mirror 20 as shown in FIG. 2, 3 or 4 and a mirror 20 with the reflectivity R as shown in FIG. 14. Along with the active zone 30, these two mirrors 20 can form the resonator of the laser 21. Thus, the lasers 21 shown in

FIGS. 6, 7, 8 and 9 can each have a mirror 20 as described in FIGS. 1, 2A, 2B, 3, 4, 5, 10, 11, 12 and 13 and a mirror 20 with the reflectivity R as shown in FIG. 14.

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

The features and exemplary embodiments described in connection with the figures can be combined with one another in accordance with further exemplary embodiments, even if not all combinations are explicitly described. Furthermore, the exemplary embodiments described in connection with the figures may alternatively or additionally have further features as described in the general part.

The invention is not limited to the exemplary embodiments by the description based on the same. Rather, the invention includes any new feature as well as any combination of features, which includes in particular any combination of features in the patent claims, even if this feature or combination itself is not explicitly stated in the patent claims or embodiments.

1. A mirror for a laser, the mirror comprising:
a layer stack having:
at least one first layer comprising a first material, and
at least one second layer comprising a second material, wherein
the layer stack has a stacking direction,
the first material has a first refractive index and the second material has a second refractive index,
the first refractive index and the second refractive index differ by at least 0.2, and
the reflectivity of the mirror in the case where a first exit medium, which is at least in places translucent for electromagnetic radiation of a predeterminable wavelength, is adjacent to the mirror differs by less than 10% from the reflectivity of the mirror in the case where a second exit medium, which differs from the first exit medium and is at least in places translucent for electromagnetic radiation of the predeterminable wavelength, is adjacent to the mirror, for a wavelength range of at least ±20 nm around the predeterminable wavelength.

2. The mirror according to claim 1, wherein all layers of the layer stack have different layer thicknesses along the stacking direction.

3. The mirror according to claim 1, wherein the reflectivity of the mirror in the case where the first exit medium is adjacent to the mirror and in the case where the second exit medium is adjacent to the mirror is less than 3% for a wavelength range of at least 40 nm.

4. The mirror according to claim 3, wherein the wavelength range of at least 40 nm extends over wavelengths which are greater than a target wavelength of the laser.

5. The mirror according to claim 1, wherein the first material and the second material each comprise at least one of an oxide, a nitride and an oxynitride.

6. The mirror according to claim 1, wherein the layer stack has a further first layer comprising the first material and a further second layer comprising the second material, wherein the further first layer is arranged between the second layer and the further second layer.

7. The mirror according to claim 1, wherein the layer thickness of each layer of the layer stack is at most 500 nm.

8. The mirror according to claim 1, wherein the first material and the second material each comprise at least one of the following substances: Al, Ce, Ga, Hf, In, Mg, Nb, Rh, Sb, Si, Sn, Ta, Ti, Zn, Zr.

9. The mirror according to claim 1, wherein the first material comprises aluminum oxide.

10. The mirror according to claim 1, wherein the second material comprises tantalum oxide.

11. The mirror according to claim 1, wherein the layer stack has a total of three first layers, three second layers and three third layers, wherein the third layers each comprise a third material.

12. The mirror according to claim 11, wherein the third material comprises silicon.

13. The mirror according to claims 1, wherein the layer stack has a total of five first layers and five second layers.

14. The mirror according to claim 1, wherein
the layer stack has a total of three first layers, three second layers and three third layers, wherein the third layers each comprise a third material,
the three first layers each have different layer thicknesses along the stacking direction,
the three second layers each have different layer thicknesses along the stacking direction (z),
the three third layers each have different layer thicknesses along the stacking direction,
third material is different from the first material and the second material.

15. A laser comprising the mirror according to claim 1, wherein the laser has an active zone and a further mirror.

16. The laser according to claim 15, wherein the first exit medium or the second exit medium, which has an extension along a main extension direction (x) of the active zone of at least 1 μm, is arranged on the side of the mirror facing away from the active zone.

17. A laser component comprising:
a laser according to claim 15, and
the first exit medium or the second exit medium.

18. The laser component according to claim 17, which has an optical element adjacent to the first exit medium or the second exit medium.

19. The laser component according to claim 18, wherein a coating is arranged between the optical element and the first exit medium or the second exit medium, which coating has a reflectivity of less than 2% for the predeterminable wavelength.

20. The laser component according to claim 17, wherein the mirror has a main extension plane which is parallel to the main extension plane of the active zone.
